(19) United States
(12) Patent Application Publication
(10) Pub. No.: US 2023/0274947 A1
(43) Pub. Date: Aug. 31, 2023

(54) SELECTIVE THERMAL ETCHING METHODS OF METAL OR METAL-CONTAINING MATERIALS FOR SEMICONDUCTOR MANUFACTURING

(71) Applicants: American Air Liquide, Inc., Fremont, CA (US); L'Air Liquide, Société Anonyme pour I'Etude et I'Exploitation des Procédés Georges Claude, Paris (FR)

(72) Inventors: Rocio Alejandra ARTEAGA MULLER, Yokosuka (JP); Masato HIRAI, Yokosuka (JP); Rapheal ROCHAT, Yokosuka (JP); Jean-Marc GIRARD, Versailles (FR); Venkateswara R. PALLEM, Hockessin, DE (US); Nicolas BLASCO, Grenoble (FR); Nicolas GOSSET, Yokosuka (JP); Megumi ISAJI, Yokosuka (JP)

(21) Appl. No.: 18/016,314

(22) PCT Filed: Jul. 13, 2021
(86) PCT No.: PCT/US2021/041368

§ 371 Date: Jan. 13, 2023

Related U.S. Application Data
(60) Provisional application No. 63/050,963, filed on Jul. 13, 2020.

(51) Int. Cl. H01L 21/3213; H01L 21/02

(52) U.S. Cl. CPC H01L 21/32138; H01L 21/02068; H10B 43/27

(57) ABSTRACT

In described embodiments, methods for selective etching (thermal etching) of metals, especially molybdenum- and tungsten-containing materials, and titanium nitride, using thionyl chloride (SOCl₂) as an etching gas at low temperatures and low pressure without a need of plasma, for device manufacturing processes and for process chamber cleanings are disclosed. Methods for cleaning reaction product deposits from interior surface of a reactor chamber or from a substrate within said reaction chamber using thionyl chloride (SOCl₂) at low temperatures and low pressure without a need of plasma are also disclosed. An additional co-reactant such as hydrogen may be used in combination with thionyl chloride. The processes are carried out in temperature ranging from approximately 150° C. to approximately 600° C., pressure under<100 Torr without the need of a plasma-activation.

### CROSS REFERENCE TO RELATED APPLICATIONS

This application claims priority to US Provisional Patent Application No. 63,050,963, filed Jul. 13, 2020, the entire contents of which are incorporated herein by reference.

### TECHNICAL FIELD

The present invention relates to methods for selective dry etching of metals, in particular, to methods for thermal etching of molybdenum- and tungsten-containing materials, and titanium nitride using thionyl chloride (SOCl₂) as an etching gas at temperature ranging from approximately 150° C. to approximately 600° C. and pressure<100 Torr without a need of plasma, for semiconductor manufacturing and chamber cleanings.

### BACKGROUND

Recently, molybdenum and molybdenum-containing materials have gained importance in semiconductor device manufacturing. Considered applications for pure molybdenum include back-end metallization, middle-of-line (MOL) layers, 3D NAND control gates, electrodes, etc. Molybdenum-containing materials, such as Molybdenum disulfide (transistors), Molybdenum oxides (DRAM capacitors), Molybdenum nitrides (diffusion barriers), have also received increased attention recently. Other metals, such as tungsten, and metal-containing films, such as titanium nitride, are still and continuously indispensable for semiconductor device manufacturing processes. During the semiconductor device manufacturing processes, material layers are deposited and then etched. Most commonly, the deposition process occurs through gas-phase deposition, for example by chemical vapor deposition (CVD) or atomic layer deposition (ALD), using various activation sources, e.g., heat, plasma, UV, etc. Etching can be performed as well through gas-phase etching processes (i.e., dry etching) by thermal, plasma or other activations, or using liquid-phase chemicals (i.e., wet etching). Etching with plasma-activation can be highly efficient and fast but may also lead to significant damage of the device, underlayers, and/or process chamber.

The continuous growth of complexity in semiconductor devices also calls for selective processes, such as area selective deposition, area selective deposition-etching (ASD-E or ASDE) and material selective etching. These processes are still relatively limited and the development of this field is highly necessary. It is therefore important to be able to etch these materials using desirable processes, preferably through a dry etching process, with a low thermal budget and low process pressure. It is especially desired to have a dry etching process that can clean the deposition chambers to avoid accumulation of deposits and particle formation that could be the origin of cross contamination issues. The cleaning of process chambers from metal contaminants is an essential step performed during a certain number of deposition cycles. Removal of residues from the deposition surface chamber typically involves the usage of greenhouse gases, for example, C₂F₆ in RF plasma discharge or NF₃ in remote plasma discharge.

Thus, there is a need for etching of metals and metal-containing films, especially molybdenum, without the need of plasma, for the device manufacturing process and for process chamber cleaning.

Currently molybdenum-containing materials etching and metal or metal-containing films dry etching have been limited. Wet processes using nitric acid, phosphoric acid, acetic acid or peroxide/acid/alkaline solutions, or combinations thereof have been disclosed, such as, US 20150079785 to Tan et al.; Lin et al., Corrosion Science, 53 (2011) 3055-3057; Lin et al., Angew. Chem. Int. Ed., 2010, 49, 7929-7932; F. W. Youny, J Appl. Phys., 33, 749 (1962); Jung et al., J. Vac. Sci. Technol. A, 15(3), May/June 1997; Chaves et al., J. Electrochem. Soc., 148 911), G640-643 (2001); Panias et al., Hydrometallurgy, 42 (1996) 257-265. However, as for dry etching, there have been a limited number of methods. For example, a process using carbon tetrachloride in combination with oxygen plasma or boron trichloride as etchant, including U.S. Pat. No. 8,481,434 to Miya et al.; U.S. Pat. No. 8,163,620 to Li et al; U.S. Pat. No. 9,773,683 to Gupta et al.; JP 62280336; Park et al., Electrochem. Solid-Sate Let., 11 (4) h71-h73 (2008); Mercier et al., Surface & Coating Tech., 260 (2014) 126-132; Muroi et al., J. Crystal Growth, 529 (2020) 125301; Kitagawa et al., Japanese J. Appl. Phys., Vol. 45, No. 10, 2006, pp. L297-L300.

US 20150079786 to Tan et al. discloses a method directed to non-specific metal cleaning method includes a reference for milder plasma-free dry or wet cleaning using a combination of thionyl chloride and amines.

Lin et al. (Angew. Chem. Int. Ed., 2010, 49, 7929-7932) describe various noble metals can be dissolved in organic solutions with high dissolution rates under mild conditions by using thionyl chloride (SOCl₂) and organic solvents/reagents (pyridine, N,N-dimethylformamide, and imidazole). Varying the composition of the solvent and reaction conditions even allows the selective dissolution of noble metals (see picture).

U.S. Pat. No. 10,240,230 issued to Odedra R. discloses a method for cleaning metal oxides using AOₘXₙ, where A=C, N, S; O=oxygen; X=halogen; m>0;n>0, including thionyl chloride, at pressures between 20 and 1000 mbar using various activation methods including plasma for dry etching of MOCVD and ALD.

### SUMMARY

Disclosed are methods for etching a substrate, the methods comprising: introducing a vapor of thionyl chloride (SOCl₂, CAS number: 7719-09-7) into a reaction chamber containing the substrate that has at least one metal or metal-containing films deposited thereon; and allowing an etching reaction to proceed between SOCl₂ and the at least one metal or metal-containing films to etch the at least one metal or metal-containing film, thereby etching the substrate.

The disclosed methods may include one or more of the following aspects:
further comprising maintaining a temperature of the reaction chamber from approximately 150° C. to approximately 600° C.;
further comprising maintaining a pressure in the reaction chamber less than 100 Torr;
further comprising maintaining a pressure in the reaction chamber less than 20 mbar (or 15 Torr);
further comprising introducing a co-reactant into the reaction chamber;
further comprising introducing a co-reactant into the reaction chamber in a continuous mode;
further comprising introducing a co-reactant into the reaction chamber in a pulsing mode;
further comprising introducing a co-reactant into the reaction chamber in a cyclic mode;
the co-reactant being H₂, F₂, NO, O₂, COS, CO₂, CO, NO₂, SO₂, O₃, Cl₂, HF, HBr or HCl;
the co-reactant being H₂;
the vapor of thionyl chloride including an inert gas;
the inert gas being selected from N₂, Ar, Kr, Ne, He, Xe, or combinations thereof;
the inert gas being N₂ or Ar;
SOCl₂ being not activated by a plasma;
the substrate being a pattern containing silicon-containing and metal or metal-containing layers;
the substrate being a blanket substrate;
the at least one metal or metal-containing film being selectively etched;
the at least one metal or metal-containing film containing Mo-containing materials, W-containing materials, Ti-containing materials, Ta-containing materials, Nb-containing, Ru-containing, Rh-containing materials, Co-containing materials, Ni-containing materials, Fe-containing materials, Hf-containing materials, Zr-containing materials, V-containing materials or combinations thereof;
the at least one metal or metal-containing film containing Mo-containing materials;
the at least one metal or metal-containing film containing W-containing materials; and
the at least one metal or metal-containing film containing titanium nitride.

Also disclosed are methods for cleaning reaction product deposits from interior surface of a reactor chamber or from a substrate within said reaction chamber, the methods comprising:

exposing the reaction product deposits to a vapor, wherein the vapor comprises a vapor of thionyl chloride (SOCl₂, CAS number: 7719-09-7);

allowing an etching reaction to proceed between SOCl₂ and the reaction product deposits to convert the reaction product deposits into volatile products; and

evacuating the remaining SOCl₂ together with substantially all volatile products of the etching reaction. The disclosed methods may include one or more of the following aspects:
further comprising maintaining a temperature of the reactor chamber from approximately 150° C. to approximately 600° C. while exposing the reaction product deposits to the vapor;
further comprising maintaining a pressure in the reaction chamber less than 100 Torr;
further comprising maintaining a pressure in the reaction chamber less than 20 mbar (or 15 Torr);
further comprising introducing a co-reactant into the reaction chamber.
the co-reactant being H₂, F₂, NO, O₂, COS, CO₂, CO, NO₂, SO₂, O₃, Cl₂, HF, HBr or HCl; and
the co-reactant being H₂;
the vapor of thionyl chloride including an inert gas;
the inert gas being selected from N₂, Ar, Kr, Ne, He, Xe, or combinations thereof;
the inert gas being N₂ or Ar;
SOCl₂ being not activated by a plasma;
the reaction product deposits containing metal and metal-containing particles or films;
the metal or metal-containing particles containing Mo-containing materials, W-containing materials, Ti-containing materials, Ta-containing materials, Nb-containing, Ru-containing, Rh-containing materials, Co-containing materials, Ni-containing materials, Fe-containing materials, Hf-containing materials, Zr-containing materials, V-containing materials or combinations thereof;
the metal or metal-containing particles containing film containing Mo-containing materials; and
the metal or metal-containing particles containing film containing W-containing materials.

### Notation and Nomenclature

The following detailed description and claims utilize a number of abbreviations, symbols, and terms, which are generally well known in the art. While definitions are typically provided with the first instance of each acronym, such as, front end of the line (FEOL). Certain abbreviations, symbols, and terms are used throughout the following description and claims, and include the followings.

As used herein, the indefinite article “a” or “an” means one or more.

As used herein, “about” or “around” or “approximately” in the text or in a claim means±10% of the value stated.

As used herein, “room temperature” in the text or in a claim means from approximately 20° C. to approximately 25° C.

The term “ambient conditions” refers to an environment temperature (i.e., ambient temperature) approximately 20° C. to approximately 25° C. and an environment pressure (ambient temperature) approximately 1 atm or 1 bar.

The term “substrate” refers to a material or materials on which a process is conducted. The substrate may refer to a wafer having a material or materials on which a process is conducted. The substrates may be any suitable wafer used in semiconductor, photovoltaic, flat panel, or LCD-TFT device manufacturing. The substrate may also have one or more layers of differing materials already deposited upon it from a previous manufacturing step. For example, the wafers may include silicon layers (e.g., crystalline, amorphous, porous, etc.), silicon containing layers (e.g., SiO₂, SiN, SiON, SiC, SiCN, SiOCN, SiCOH, etc.), metal-containing layers (e.g., copper, cobalt, ruthenium, tungsten, manganese, platinum, palladium, nickel, ruthenium, gold, etc.) or combinations thereof. Furthermore, the substrate may be planar or patterned. The substrate may be an organic patterned photoresist film. The substrate may include layers of oxides which are used as dielectric materials in MEMS, 3D NAND, MIM, DRAM, or FeRam device applications (for example, ZrO₂ based materials, HfO₂ based materials, TiO₂ based materials, rare earth oxide based materials, ternary oxide based materials, etc.) or nitride-based films (for example, TaN, TiN, NbN) that are used as electrodes. One of ordinary skill in the art will recognize that the terms “film” or “layer” used herein refer to a thickness of some material laid on or spread over a surface and that the surface may be a trench or a line. Throughout the specification and claims, the wafer and any associated layers thereon are referred to as substrates.

The term “wafer” or “patterned wafer” refers to a wafer having a stack of silicon-containing films on a substrate and a patterned hardmask layer on the stack of silicon-containing films formed for pattern etch.

The term “pattern etch” or “patterned etch” refers to etching a non-planar structure, such as a patterned mask layer on a stack of silicon-containing films.

As used herein, the term “etch” or “etching” refers to thermal etch or thermal etching without a need of plasma herein, which means to remove material via chemical vapor reaction between the etching gas and substrate and refers to an isotropic etching process and/or an anisotropic etching process. The isotropic etch process involves a chemical reaction between the etching compound and the substrate resulting in part of material on the substrate being removed. This type of etching process includes chemical dry etching, vapor phase chemical etching, thermal dry etching, or the like. The isotropic etch process produces a lateral or horizontal etch profile in a substrate. The isotropic etch process produces recesses or horizontal recesses on a sidewall of a pre-formed aperture in a substrate. Thermal etching has advantages over plasma etching, for example, thermal etching avoids sublayer damages that may be cause by plasma etching.

The term “mask” refers to a layer that resists etching. The mask layer may have patterns and may be located above the layer to be etched. The mask layer also refers to a hardmask layer.

The term “etch stop” refers to a layer below the layer to be etched that protects layers underneath.

The term “device channel” refers to layers that are part of actual device and any damage to it will affect device performance.

The term “aspect ratio” refers to a ratio of the height of a trench (or via) to the width of the trench (or the diameter of the via).

The term “selectivity” means the ratio of the etch rate of one material to the etch rate of another material. The term “selective etch” or “selectively etch” means to etch one material more than another material, or in other words to have a greater or less than 1:1 etch selectivity between two materials.

Note that herein, the terms “film” and “layer” may be used interchangeably.

It is understood that a film may correspond to, or related to a layer, and that the layer may refer to the film. Furthermore, one of ordinary skill in the art will recognize that the terms “film” or “layer” used herein refer to a thickness of some material laid on or spread over a surface and that the surface may range from as large as the entire wafer to as small as a trench or a line.

Note that herein, the terms “etching compound” and “etching gas” may be used interchangeably. It is understood that an etching compound may correspond to, or related to an etching gas, and that the etching gas may refer to the etching compound.

The terms “via”, “aperture” and “hole” are sometimes used interchangeably, and generally mean an opening in an interlayer insulator.

As used herein, the abbreviation “NAND” refers to a “Negated AND” or “Not AND” gate; the abbreviation “2D” refers to 2 dimensional gate structures on a planar substrate; the abbreviation “3D” refers to 3 dimensional or vertical gate structures, wherein the gate structures are stacked in the vertical direction.

The standard abbreviations of the elements from the periodic table of elements are used herein. It should be understood that elements may be referred to by these abbreviations (e.g., Si refers to silicon, N refers to nitrogen, O refers to oxygen, C refers to carbon, H refers to hydrogen, F refers to fluorine, etc.).

The unique CAS registry numbers (i.e., “CAS”) assigned by the Chemical Abstract Service are provided to help better identify the molecules disclosed.

Ranges may be expressed herein as from about one particular value, and/or to about another particular value. When such a range is expressed, it is to be understood that another embodiment is from the one particular value and/or to the other particular value, along with all combinations within said range.

Reference herein to “one embodiment” or “an embodiment” means that a particular feature, structure, or characteristic described in connection with the embodiment may be included in at least one embodiment of the invention. The appearances of the phrase “in one embodiment” in various places in the specification are not necessarily all referring to the same embodiment, nor are separate or alternative embodiments necessarily mutually exclusive of other embodiments. The same applies to the term “implementation.”

### BRIEF DESCRIPTION OF THE DRAWINGS

For a further understanding of the nature and objects of the present invention, reference should be made to the following detailed description, taken in conjunction with the accompanying drawings, in which like elements are given the same or analogous reference numbers and wherein:

FIG. 1a is a schematic representation of an exemplary cross-sectional side view of an exemplary work piece to be etched;

FIG. 1b is a schematic representation of an exemplary cross-sectional side view of an isotropic opening formed in the substrate shown in FIG. 1a;

FIG. 2a is a schematic representation of an exemplary cross-sectional side view of gate dielectric and metal deposited in a 3D NAND opening;

FIG. 2b is a schematic representation of an exemplary cross-sectional side view of vertically etched metal material from the 3D NAND opening shown in FIG. 2a;

FIG. 3 is a set of SEM images over various times for Mo etching using SOCl₂ at 250° C.;

FIG. 4 is a set of SEM images over various times for Mo etching using SOCl₂ at 300° C.;

FIG. 5 is XPS results of Mo film on SiO₂ before etching;

FIG. 6 is a set of XPS results of Mo films at 300° C.;

FIG. 7 is a set of XPS results of Mo films at 350° C.:

FIG. 8 is a set of XPS results of Mo films at 400° C.;

FIG. 9 is a set of XPS results of HfO₂ film on SiO₂ before etching;

FIG. 10 is a set of XPS results of HfO₂ film at 400° C. with 5% of SOCl₂;

FIG. 11 is a set of XPS results of ZrO₂ film on SiO₂ before etching;

FIG. 12 is a set of XPS results of ZrO₂ film at 400° C. with 5% of SOCl₂;

FIG. 13 is a set of etch rates of SOCl₂ over temperature (T-SiO₂ (thermal SiO₂) TiO₂, TiN, Mo and InOₓ);

FIG. 14 is a set of etch rates of SOCl₂ over temperature study (Poly-Si, SiN, T-SiO₂ Ru and W);

FIG. 15 is a set of etch rate of SOCl₂ over concentrations of SOCl₂ (Poly-Si, SiN and T-SiO₂);

FIG. 16 is a set of etch rate of SOCl₂ over concentrations of SOCl₂ (SiN, TiO₂ and TiN);

FIG. 17 is a set of etch rates of SOCl₂ over concentration effect (SiN, T-SiO₂, Mo and InOₓ);

FIG. 18 is a set of selectivity results of SOCl₂ etching Poly-Si;

FIG. 19 is a set of selectivity results of SOCl₂ etching to SiN;

FIG. 20a is an image of the quart tube chamber before cleaning;

FIG. 20b is an image of the quart tube chamber after cleaning;

FIG. 21a is an image of the hot area of the quart tube chamber before cleaning; and

FIG. 21b is an image of the hot area of the quart tube chamber after cleaning.

### DESCRIPTION OF PREFERRED EMBODIMENTS

Disclosed are methods for selective dry etching of metals or metal-containing films, especially molybdenum- and tungsten-containing materials, and titanium nitride, using thionyl chloride (SOCl₂) (CAS number: 7719-09-7) with or without hydrogen as an etching gas at low temperatures and low pressure without a need of plasma, for device manufacturing processes and for process chamber cleanings. The metal or metal-containing film contains Mo-containing materials, W-containing materials, Ti-containing materials, Ta-containing materials, Nb-containing, Ru-containing, Rh-containing materials, Co-containing materials, Ni-containing materials, Fe-containing materials, Hf-containing materials, Zr-containing materials, V-containing materials or combinations thereof. The disclosed also include methods for cleaning reaction product deposits from interior surface of a reactor chamber or from a substrate within said reaction chamber using thionyl chloride (SOCl₂) at low temperatures and low pressure without a need of plasma. The product deposits include metal and metal-containing particles or films. A co-reactant such as hydrogen may be used in combination with thionyl chloride. The co-reactant is selected from H₂, F₂, NO, O₂, COS, CO₂, CO, NO₂, SO₂, O₃, Cl₂, HF, HBr or HCl. The disclosed methods operate at low temperatures ranging from approximately 150° C. to approximately 600° C., low pressures under<100 Torr without the need of a plasma-activation.

Furthermore, selective etching of these materials versus commonly used substrate materials, such as silicon oxide or aluminum oxide may be achieved with the disclosed methods.

The disclosed methods may be used to thermally etch silicon-containing layers on a substrate. The disclosed etching method may be useful in the manufacture of semiconductor devices such as NAND or 3D NAND gates or Flash or DRAM memory. The disclosed etching methods may be used in other areas of applications, such as different front end of the line (FEOL) and back end of the line (BEOL) etch applications. Additionally, the disclosed methods may also be used for etching Si in 3D TSV (Through Silicon Via) etch applications for interconnecting memory substrates on logic substrates.

The disclosed methods are based on a halogenating reagent, SOCl₂, which is commonly used as an inexpensive and readily available halogenating agent in synthetic chemistry. The disclosed methods utilize the properties of SOCl₂ to convert metal-containing materials into volatile chloride-containing metal compounds.

Exemplary films to be etched may include Mo-containing films, Ti-containing films, Ta-containing films, W-containing films, Nb-containing, Ru-containing, Rh-containing films, Co-containing films, Ni-containing films, Fe-containing films, Hf-containing films, Zr-containing films, V-containing films or combination thereof. Exemplary films to be etched may alternatively include metal films, such as Mo, oxides thereof, nitrides thereof, or combinations thereof. For example, in the case of the metal-containing materials being molybdenum oxide, one possible reaction is SOCl₂ may react with molybdenum oxide to form volatile chloride-containing molybdenum compounds and volatile sulfur compounds.

The boiling point of SOCl₂ is around 79° C. SOCl₂ may decompose above around 80° C. to form a mixture of SO₂, Cl₂, S₂Cl₂ and related etch-active and inactive species. In addition, the etching performance of SOCl₂ may be improved by adding hydrogen as an additional reactant to the above mixture, resulting in a two component etching process. Besides, the etching with the halogenating reagent, SOCl₂, and subsequent treatment with H₂ may be used to eliminate metal and metal oxide residual layers attached to the wall of a reaction chamber in a deposition tool. In the disclosed methods, etching temperature is in a range of approximately 150° C. to approximately 600° C., in which SOCl₂ is a vapor and may decompose to the mixture of SO₂, Cl₂, S₂Cl₂ and the related etch-active and inactive species. The disclosed methods do not need plasma-activated SOCl₂ and H₂.

The disclosed methods comprise the usage of one component SOCl₂ alone or a mixture of two components (e.g., SOCl₂ and H₂) to achieve selective and non-selective thermal etching with applications in logic and memory patterning processes. The mixture of the two components include SOCl₂ and a co-reactant. The co-reactant is selected from H₂, F₂, NO, O₂, COS, CO₂, CO, NO₂, SO₂O₃, Cl₂, HF, HBr or HCl. The co-reactant may be introduced into a reaction chamber in a continuous, pulsing or cyclic mode. SOCl₂ or the mixture of two components (e.g., SOCl₂ and H₂) may provide high etch selectivity to metal or metal-containing films versus mask layers, photoresist, etch stop layers, device channel materials and silicon-containing films, in applications such as DRAM and 3D NAND. SOCl₂ or the mixture of two components may provide infinite selectivity for wide process conditions of etching. Herein the selectivity refers to the etching rate ratio of two different etched layers.

SOCl₂ is provided at greater than 95% v/v purity, preferably at greater than 99.99% v/v purity, and more preferably at greater than 99.999% v/v purity. SOCl₂ contains less than 5% by volume trace gas impurities, with less than 150 ppm by volume of impurity gases, such as SO₂Cl₂, S₂Cl₂, SCl₂, SO₂, Cl₂, acid impurities contained in said trace gaseous impurities. Preferably, the water content in SOCl₂ and or the mixture of SOCl₂ and H₂ is less than 20 ppm by weight.

SOCl₂ or the mixture of two components is suitable for dry etching semiconductor structures, such as, channel holes, gate trenches, staircase contacts, slits, capacitor holes, contact holes, etc., in metal/metal-containing films without a need of plasma activation. SOCl₂ or the mixture of two components may etch desired metal or metal-containing layers with less damage to underlayers, such as p-Si or crystalline Si channel structures during etching than other etching processes, such as plasma etching.

In one embodiment, a substrate having a material (e.g., a metal or metal-containing layer) to be etched, such as a semiconductor workpiece, is loaded into a reaction space or process chamber that is heated to a predetermined temperature. The semiconductor workpiece may be a workpiece for producing 3D NAND or DRAM structures, etc., in semiconductor applications. The reaction chamber may contain one or more than one substrate. For example, the reaction chamber may contain from 1 to 200 substrate wafers having from 25.4 mm to 450 mm diameters. The substrates may be any suitable substrates used in semiconductor, photovoltaic, flat panel or LCD-TFT device manufacturing. Examples of suitable substrates include wafers, such as silicon, silica, glass, or GaAs wafers. The wafer will have multiple films or layers deposited on it from previous manufacturing steps, including metal or metal-containing films or layers. The layers may or may not be patterned. Examples of suitable layers include without limitation molybdenum- and tungsten-containing layer materials, and titanium nitride layer material, mask layer materials such as amorphous carbon with or without dopants, antireflective coatings, photoresist materials, tungsten, titanium nitride, tantalum nitride or combinations thereof, etch stop layer or landing layer materials such as silicon nitride, polysilicon, crystalline silicon, silicon carbide, SiCN or combinations thereof, etc. Throughout the specification and claims, the wafer and any associated layers thereon are referred to as substrates.

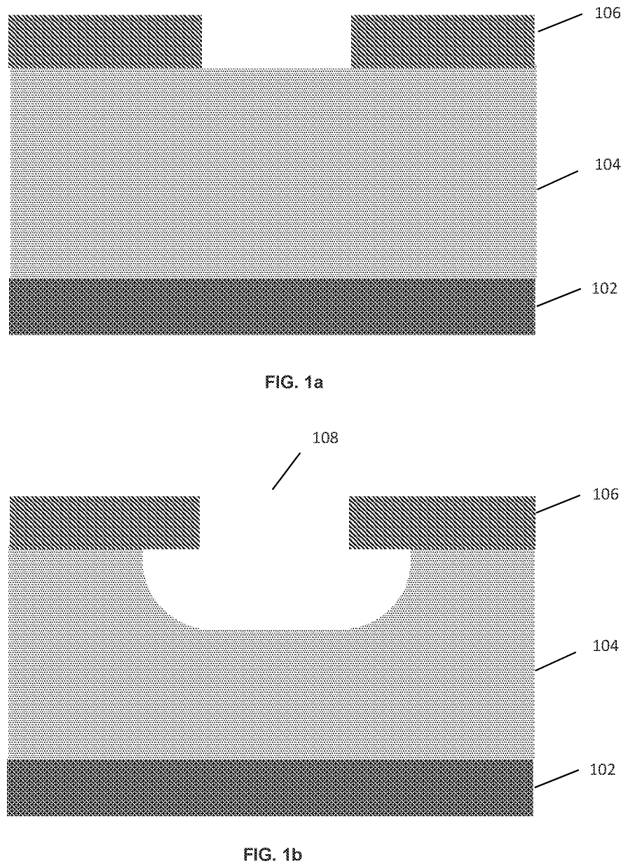

The material to be etched in the substrate or the material to be etched in the semiconductor workpiece is selectively etched by SOCl₂ or the mixture of two components. FIG. 1a is an exemplary cross-sectional side view of an exemplary workpiece to be etched. The exemplary workpiece includes a metal or metal-containing films 104 deposited on top of a wafer such as a silicon wafer 102 and a patterned mask layer 106 deposited on top of a metal or metal-containing films 104. The patterned mask layer 106 (e.g., a-C mask layer) other layers such as antireflective coating and photoresist layer (not shown) which may be deposited on the metal or metal-containing films 104 are less reactive with SOCl₂ or the mixture of two components. Thus, SOCl₂ or the mixture of two components selectively reacts with the metal or metal-containing material to form volatile by-products thereby producing a desired isotropic opening 108 in the metal or metal-containing films 104, as shown in FIG. 1b. FIG. 1b is an exemplary cross-sectional side view of an isotropic opening formed in the substrate shown in FIG. 1a.

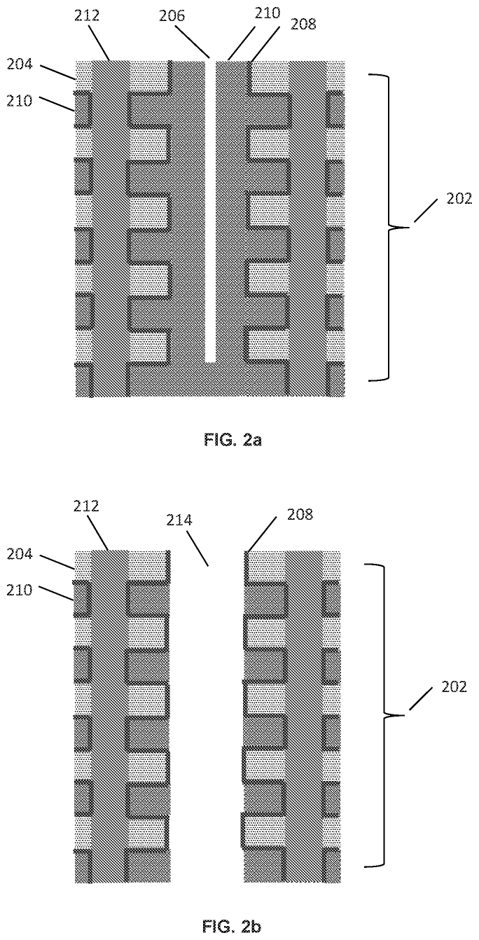

Alternatively, the material to be etched by SOCl₂ or the mixture of two components is in a 3D NAND structure such as in a gate recess process, as shown in FIG. 2a. An aperture 206 in the 3D NAND structure is deposited with a thin oxide/charge-trap layer 208 and a metal layer 210. The 3D NAND structure includes alternating layers 202 of a SiO₂ layer 204 and the metal layer 210. A silicon wafer in the bottom of the 3D NAND and a patterned hardmask layer on the top of the 3D NAND are not shown. The SiO₂ layer 204 isolates charge-trap transistors. Channels 212 is a poly-Si channel. The thin oxide/charge-trap layer 208 may be a stack of SiO₂/SiN/TaN, SiO₂/SiN/HfO₂, SiO₂/SiN/ZrO₂, etc. The metal layer 210 may be a layer of W, Mo, Ru, etc. FIG. 2b is an exemplary cross-sectional side view of a vertically etched 3D NAND structure of FIG. 2a using SOCl₂ or the mixture of the two components. The metal layer 210 is vertically etched by SOCl₂ or the mixture of the two components without plasma activation, forming an aperture 214 that is an enlarged aperture 206 in FIG. 2a and separates gate nodes in the gate recess process. One of ordinary skill in the art will recognize that the stack of layers in the 3D NAND, the apertures and geometry of layers depicted in FIG. 2a and FIG. 2b are provided for exemplary purposes only.

The disclosed methods also include cleaning a deposition/reaction chamber or removing residual layers deposited on the wall of the deposition chamber by etching residual deposits as target materials using pure SOCl₂ or a mixture of SOCl₂ with H₂. The residual deposits are reaction product deposits from the interior surface of a reactor chamber or from a substrate within the reaction chamber. SOCl₂ or the mixture of two components reacts with the residual deposits to form volatile products, such as volatile chloride-containing metal compounds. The residual deposits may contain metal or metal-containing particles and/or films. The method for cleaning reaction product deposits from interior surface of a reactor chamber or from a substrate within said reaction chamber comprises exposing the reaction product deposits to a vapor, wherein the vapor comprises a vapor of an etchant SOCl₂ or the mixture of two components, allowing an etching reaction to proceed between SOCl₂ or the mixture of two components and the reaction product deposits to convert the reaction product deposits into volatile products, and evacuating the remaining SOCl₂ or the mixture of two components together with substantially all products of the etching reaction.

In the disclosed methods, the vapor of SOCl₂ or the mixture of two components is introduced into the reaction chamber containing the substrate and metal or metal-containing films deposited thereon. The vapor may be introduced to the chamber at a flow rate ranging from approximately 0.1 sccm to approximately 2 sim. One of ordinary skills in the art will recognize that the flow rate may vary from tool to tool.

SOCl₂ may be supplied either in neat form or in a blend with an inert gas, such as N₂, Ar, Kr, Ne, He, Xe, etc., preferably N₂ or Ar, or hydrogen. Other exemplary gases with which SOCl₂ may be mixed include additional gases, such as F₂, NO, O₂, COS, CO₂, CO, NO₂, SO₂O₃, Cl₂, HF, HBr, HCl. SOCl₂ may be present in varying concentrations in the blend. The neat or blended SOCl₂ may be fed to a vaporizer where it is vaporized before it is introduced into the reactor.

Alternatively, the neat or blended SOCl₂ may be vaporized by passing a carrier gas into a container containing SOCl₂ or by bubbling the carrier gas into SOCl₂. The carrier gas may include, but is not limited to, Ar, He, N₂, Kr, Xe, Ne and mixtures thereof. Bubbling with a carrier gas may also remove any dissolved oxygen present in the neat or blended SOCl₂ solution. The carrier gas and SOCl₂ are then introduced into the reactor as a vapor.

SOCl₂ is liquid in ambient conditions. If necessary, a container containing SOCl₂ may be heated to a temperature that permits SOCl₂ to be a vapor for delivery into an etching tool. The container may be maintained at temperatures in the range of, for example, approximately 0° C. to approximately 80° C., preferably from approximately 0° C. to approximately 30° C., to permit SOCl₂ supply. Those skilled in the art recognize that the temperature of the container may be adjusted in a known manner to control the amount of SOCl₂ vaporized.

Additionally, SOCl₂ is delivered in purity ranging from 95% to 99.999% by volume and may be purified with known standard purification techniques for removal of SO₂Cl₂, S₂Cl₂, SCl₂, SO₂, Cl₂, and acid impurities.

A quadrupole mass spectrometer (QMS), FTIR may measure the activated etching gas from the chamber exhaust to determine the types and numbers of species produced. If necessary, the flow rate of the etching gas and/or the inert gas may be adjusted to increase or decrease the number of radical species produced.

SOCl₂ may be mixed with hydrogen gas either prior to introduction into the reaction chamber or inside the reaction chamber. Preferably, the SOCl₂ and H₂ gases may be mixed prior to introduction to the chamber in order to provide a uniform concentration of the entering gas.

In another alternative, the vapor of SOCl₂ may be introduced into the chamber independently of H₂, such as when two gases react or are easier to deliver independently.

The metal or metal-containing films and SOCl₂ react to form volatile by-products that are removed from the reaction chamber. The a-C mask, antireflective coating, and photoresist layer which may deposited on the metal or metal-containing films, or underlayers, such as etch stop layers, device channel materials and silicon-containing films, are less reactive with SOCl₂ or the mixture of two components. Thus, the etching gas SOCl₂ or the mixture of two components selectively reacts with the metal or metal-containing materials to form volatile by-products that is purged or evacuated subsequently.

The temperature and the pressure within the reaction chamber are held at conditions suitable for the metal or metal-containing films to react with the vapor SOCl₂. For instance, the pressure in the chamber may be held less than 100 Torr, preferably, less than 15 Torr (approximately 20 mbar), more preferably between 0.1 Torr and 15 Torr, even more preferably between 1 Torr and 10 Torr, as required by etching parameters. Likewise, the substrate temperature in the chamber may range between about approximately 150° C. to approximately 600° C., preferably between approximately 200° C. to approximately 400° C., more preferably between approximately 250° C. to approximately 300° C., depending on process requirements.

The reaction between the metal or metal-containing films and SOCl₂ or the mixture of two components results in isotropic removal of the metal or metal-containing films from the substrate.

### EXAMPLES

The following non-limiting examples are provided to further illustrate embodiments of the invention. However, the examples are not intended to be all inclusive and are not intended to limit the scope of the inventions described herein.

### Example 1: Etching of Mo Films

Etching of Mo thin films has been performed using SOCl₂ (chamber temperature (T_{cham}), chamber pressure (P_{cham}), canister temperature (T_{can}), canister Pressure (P_{can}), flow rate (FR), partial pressure (PP), residence time, etc. listed for each experiment) as the etchant gas at temperatures between 250 and 400° C. at 10 Torr. Although the samples contained a 5 nm layer of native Mo oxide on top of pure Mo film, etching has been achieved applying SOCl₂ at temperatures above 250° C.

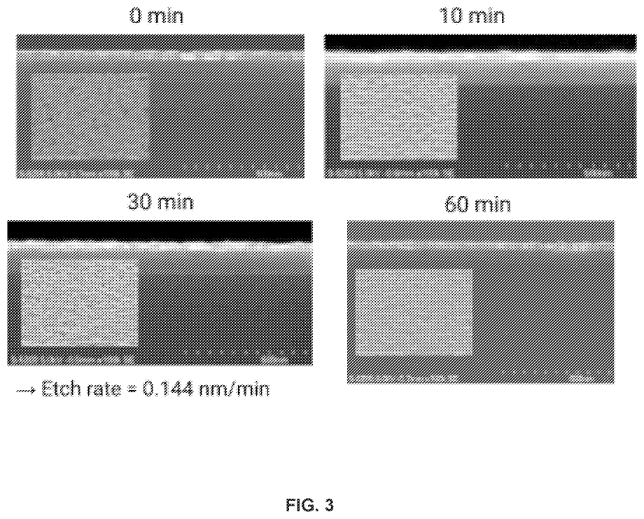

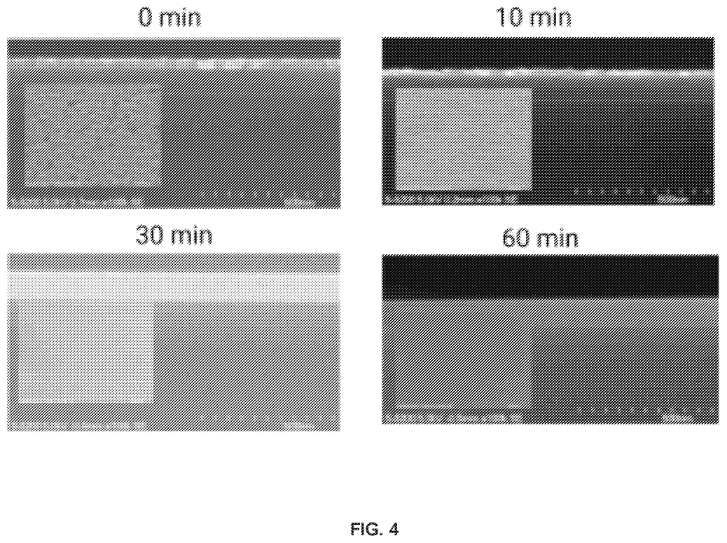

Table 1 is Mo film etching by SOCl₂ at 250° C. and 300° C., respectively, which includes the process conditions used to etch Mo film by SOCl₂ at 250° C. and 300° C., respectively. Table 2 is an Ellipsometry summary for Mo etching using SOCl₂ at 250° C. versus various times with SEM images shown in FIG. 3. Table 3 is an Ellipsometry summary for Mo etching using SOCl₂ at 300° C. versus various times with SEM images shown in FIG. 4.

Etch rates have been estimated to be 0.144 nm/min based on scanning electron microscopy (SEM) results and 0.122 nm/min based on Ellipsometry results at 250° C. and 0.806 nm/min based on SEM results and 0.862 nm/min based on Ellipsometry results at 300° C. While no sign of etching was observed at 200° C., Mo was completely removed at 400° C. within 5 min (etch rate>6.2 nm/min). This shows that SOCl₂ is an efficient etchant towards Mo at temperatures above 200° C.

TABLE 1

| | | | | | | | | Total |
|---|---|---|---|---|---|---|---|---|
| | | | | | SOCl₂ | | Resi | reaction |
| T_{cham} | P_{cham} | Ar FR | T_{can} | P_{can} | FR | PP | time | time |
| (° C.) | (Torr) | (sccm) | (° C.) | (Torr) | (sccm) | (Torr) | (sec) | (min) |
| 250 | 10 | 100 | 1 | 300 | 2.67 | 57 | 2.56 | 10 ~ 60 |
| 300 | 10 | 100 | 1 | 300 | 2.67 | 57 | 2.56 | 10 ~ 60 |

TABLE 2

| Etching temperature (° C.) | Time (min) | Etched MoThickness (nm) |
|---|---|---|
| 250 | 10 | 0.6 |
| 250 | 30 | 3.6 |
| 250 | 60 | 8.4 |

Initial Mo film 34.2 nm;
Etch rate = 0.13 nm/min

TABLE 3

| Etching temperature (° C.) | Time (min) | Etched Mo Thickness (nm) |
|---|---|---|
| 300 | 10 | 9.2 |
| 300 | 30 | 24.4 |
| 300 | 60 | 34.2 |

Initial Mo film 34.2 nm;
Etch rate = 0.82 nm/min

### Example 2: Mo Film Depth Profile Etching with SOCl₂

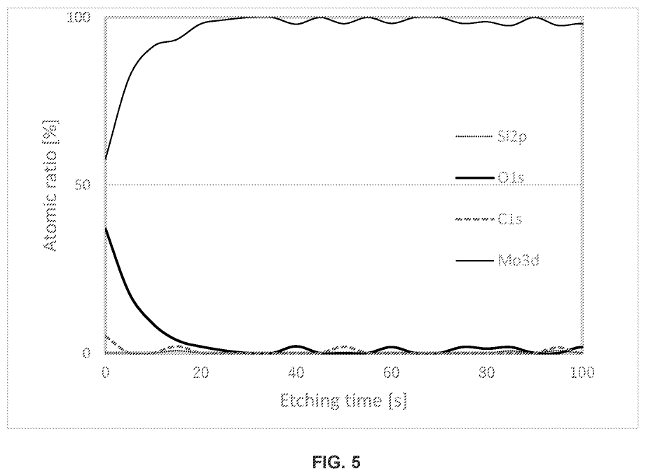

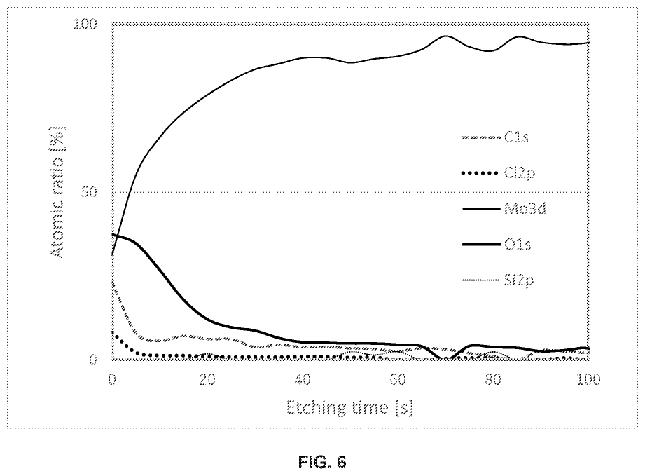

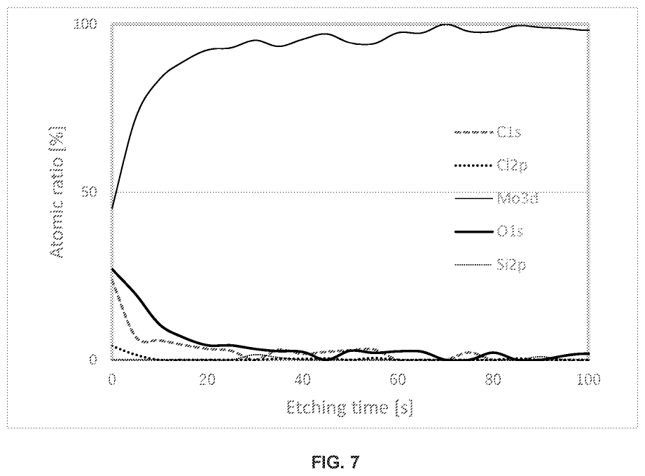

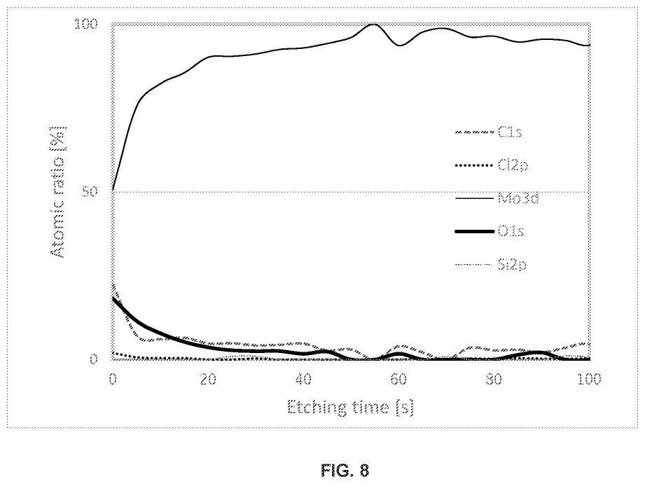

FIG. 5 is XPS results of Mo film on SiO₂ before etching. FIG. 6 to FIG. 8 are XPS results of Mo films at 300° C., 350° C. and 400° C., respectively.

### Example 3: HfO₂ Depth Profile Etching with SOCl₂

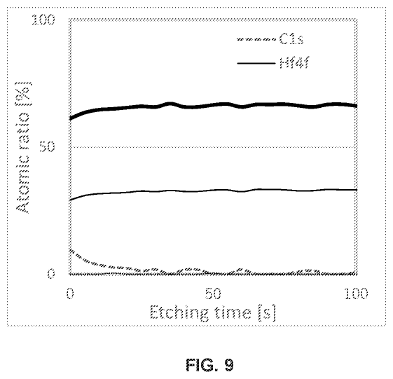

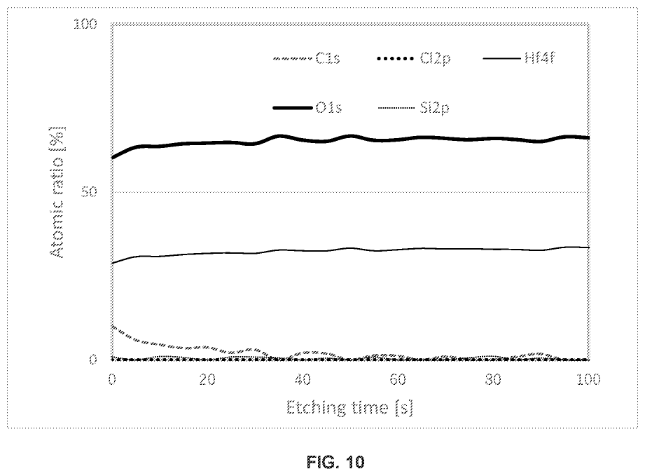

FIG. 9 is XPS results of HfO₂ film on SiO₂ before etching. FIG. 10 is XPS results of HfO₂ film at 400° C. with 5% of SOCl₂.

### Example 4: ZrO₂ Depth Profile Etching with SOCl₂

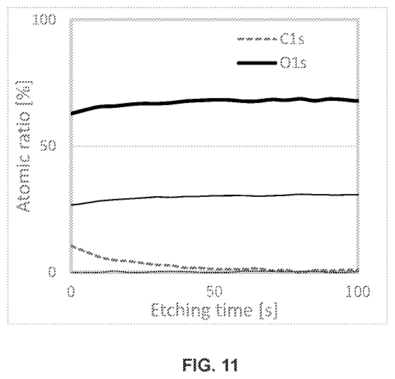

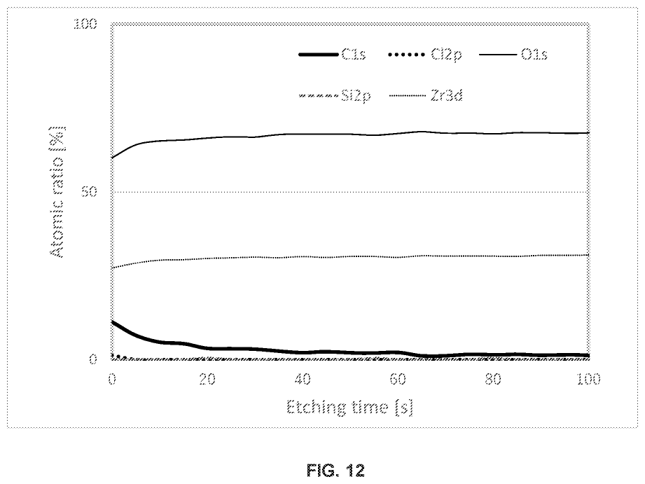

FIG. 11 is XPS results of ZrO₂ film on SiO₂ before etching. FIG. 12 is XPS results of ZrO₂ film at 400° C. with 5% of SOCl₂.

### Example 5: SOCl₂ Etch Rate

Examples 5 to 7 were carried out at the following conditions listed in Table 4.

TABLE 4

| | |
|---|---|
| Process gas (bubbling) | SOCl₂ Concentration 0.6 to 5% |
| Carrier/dilution gas flow rate | N₂ 500 sccm |
| Total flow rate | 500 sccm |
| Etching time | 15 to 1800 seconds |
| Pressure | 5 to 50 Torr |
| Temperature | 300 to 450° C. |
| Sample size | 1 cm × 1 cm |

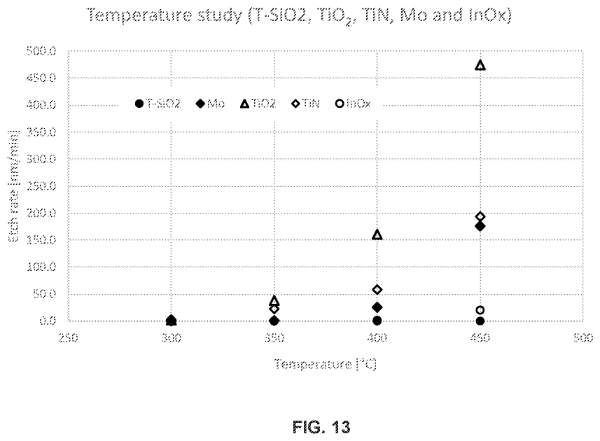

FIG. 13 is etch rates of SOCl₂ over temperature (T-SiO₂ (thermal SiO₂) TiO₂ TiN, Mo and InOₓ). The etch rates of TiO₂, TiN and Mo are increasing as the temperature increases. The etch rates of T-SiO₂ and InOₓ (x>0) remain almost zero with the temperature increasing.

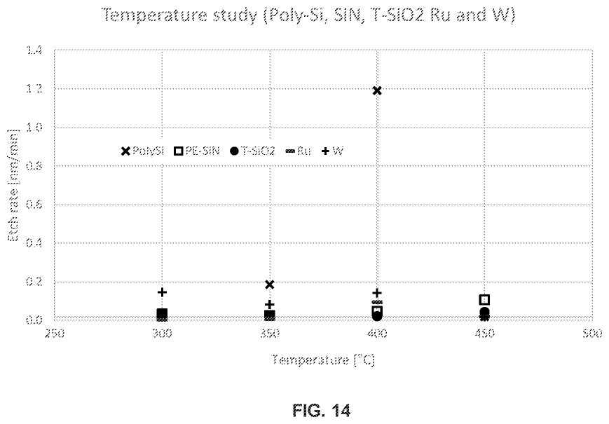

FIG. 14 is etch rates of SOCl₂ over temperature study (Poly-Si, SiN, T-SiO₂ Ru and W). The etch rate of Poly-Si reaches to 1.2 nm/min at 400° C.

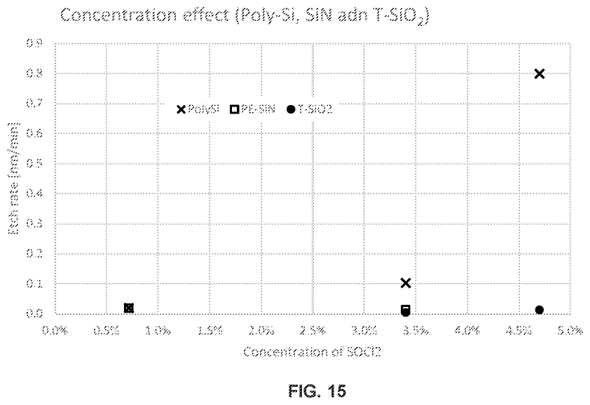

FIG. 15 is etch rate Of SOCl₂ over concentrations Of SOCl₂ (Poly-Si, SiN and T-SiO₂). The etch rate of Poly-Si is increasing as the concentration increases. The etch rate of Poly-Si reaches to 0.8 nm/min with 5.0% of SOCl₂ concentration. T-SiO₂ and plasma enhanced SiN (PE-SiN) were not etched.

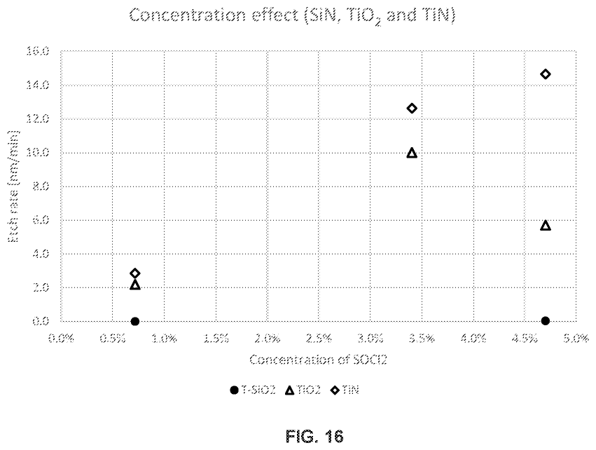

FIG. 16 is etch rate of SOCl₂ over concentrations of SOCl₂ (SiN, TiO₂ and TiN). The etch rates of TiO₂ and TiN are increasing as the concentration increases, respectively. However, the etch rate of TiO₂ has a turning point at 3.0% of SOCl₂ concentration. The etch rate of TiN has no turning points. T-SiO₂ was not etched.

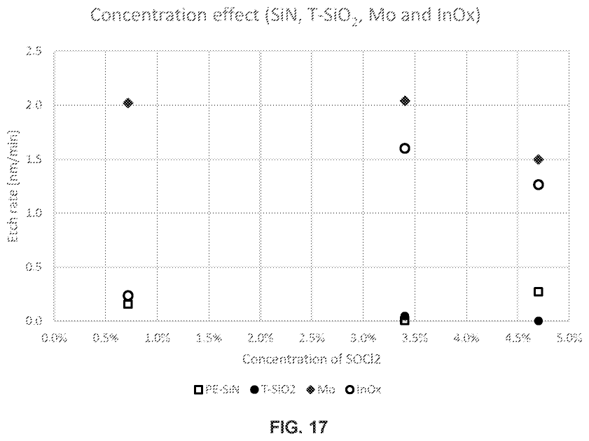

FIG. 17 is etch rate Of SOCl₂ over concentration effect (SiN, T-SiO₂, Mo and InOₓ). The etch rate of Mo maintained at 2.0 nm/min with the concentrations from 1.0% to about 3.5%, and then reduced to 1.5 nm/min with around 4.5% of SOCl₂ concentration. The etch rate of InOₓ has a turning point at around 3.5% of SOCl₂ concentration, that is, increased below around 3.5% and then reduced above around 3.5% of SOCl₂ concentration. The etchrate of T-SiO₂ almost remained close to 0 over the concentration range of 0 to 5.0%. the etch rate of PE-SiN was below around 0.25 nm/min, reduced below around 3.5% of SOCl₂ concentration and then increased above around 3.5% of SOCl₂ concentration.

### Example 6: SOCl₂ Selectivity

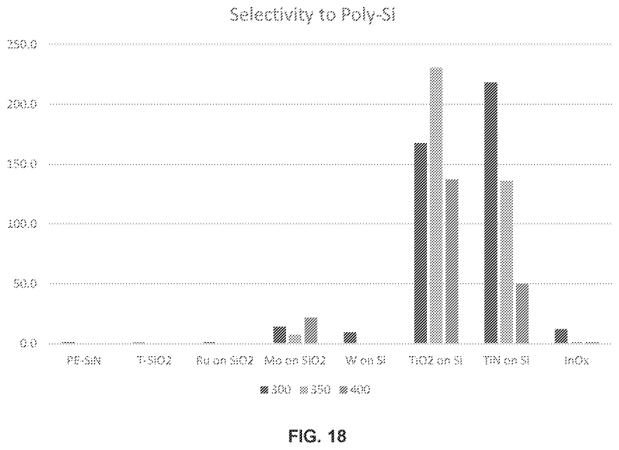

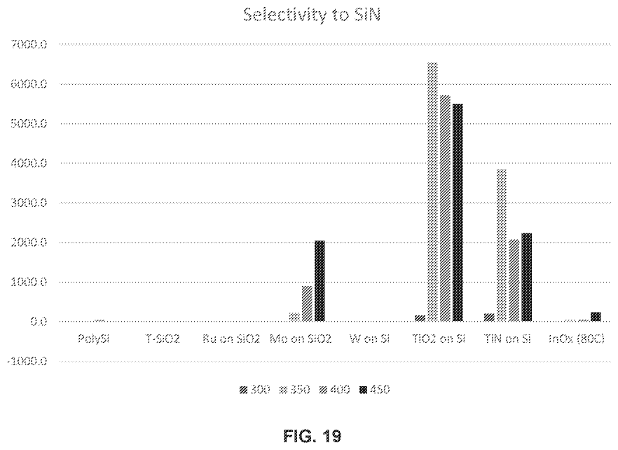

FIG. 18 is selectivity results of SOCl₂ etching Poly-Si. The etching of metal containing materials by SOCl₂ shows high selectivity to PolySi, because the etch rate of PolySi with 0.6% SOCl₂ is very low in the temperature range we investigated. The selectivity increases with increasing temperature. FIG. 19 is selectivity results of SOCl₂ etching to SiN. The etch rate of SiN in the temperature range is close to 0, therefore the selectivity of Mo, TiO₂, TiN and InOₓ to SiN were significantly high.

### Example 7: Etching Rate of Highk

HfO₂ and ZrO₂ are high-k materials which have higher relative permittivity than SiO₂. These two materials are promising insulators to replace SiO₂ for future miniaturization, but there are not many technologies that can control the amount of etching with particular precision. SOCl₂ can etch HfO₂ and ZrO₂ at sub-nm/min order at 400° C. (Table 5). This also shows the possibility of controlling the amount of etching by the SOCl₂ cycling process. FIG. 9 to FIG. 12 show the XPS results of HfO₂ and ZrO₂ before and after the SOCl₂ etching process. No SOCl₂-derived elements remain on the surface, indicating that the process is not invasive.

TABLE 5

| | 0.7% | 3.4% | 4.7% |
|---|---|---|---|
| ZrO₂ | 0.2 | 0.2 | 0.4 |
| HfO₂ | 0.2 | 0.7 | 0.2 |

### Example 8: Cleaning Mo Film Residues

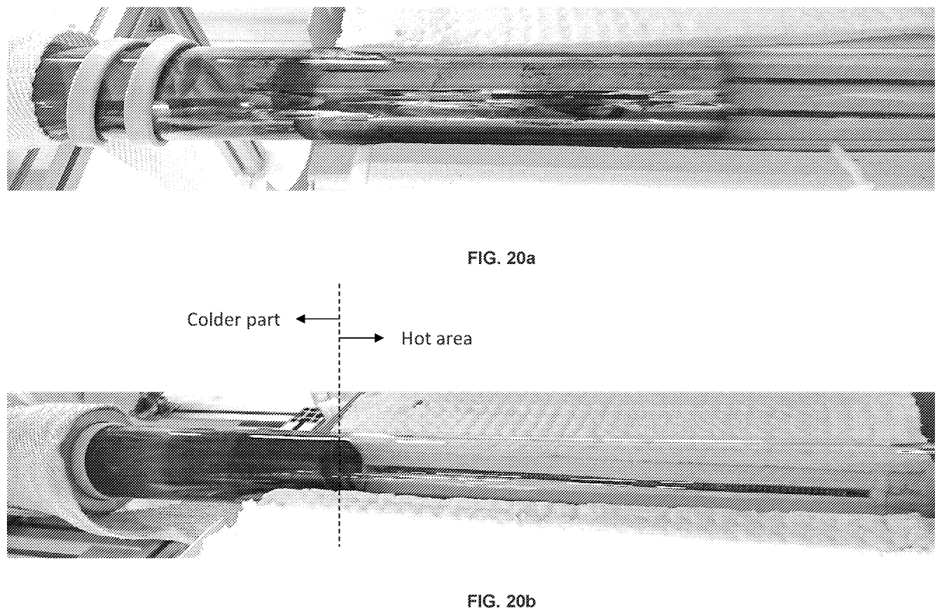

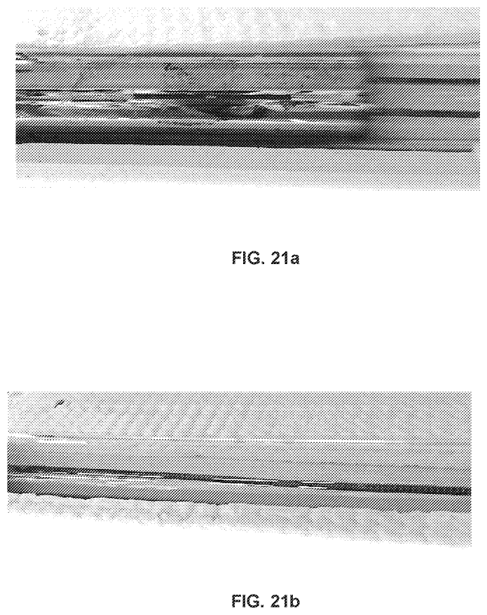

Mo films that deposited and accumulated on the inner surface of a deposition chamber are difficult to remove both mechanically and chemically. However, in the following exemplary example, it demonstrates that SOCl₂ may indeed behave as etching gas for chamber cleaning with a quart tube chamber. Table 6 is the chamber cleaning conditions using SOCl₂ at a temperature ranging from 200° C. to 400° C. to remove Mo residues in the quart tube chamber. FIG. 20a and FIG. 20b are the images of the quart tube chamber before and after cleaning. The results shows that the hot area of the quart tube chamber was clean, whereas the colder part outside the chamber still had deposits. FIG. 21a and FIG. 21b are the images of the hot area of the quart tube chamber before and after cleaning.

TABLE 6

| | | | | | | | | Total |
|---|---|---|---|---|---|---|---|---|
| | | | | | | | Resi- | re- |
| | | | | | SOCl₂ | | dence | action |
| T_{cham} | P_{cham} | Ar FR | T_{can} | P_{can} | FR | PP | time | time |
| (° C.) | (Torr) | (sccm) | (C) | (Torr) | (sccm) | (Torr) | (sec) | (min) |
| 200 ~ 400 | 10 | 135 | 1 | 300 | 2.67 | 60.94 | 2.74 | 30 |

Although the subject matter described herein may be described in the context of illustrative implementations to process one or more computing application features/operations for a computing application having user-interactive components the subject matter is not limited to these particular embodiments. Rather, the techniques described herein can be applied to any suitable type of user-interactive component execution management methods, systems, platforms, and/or apparatus.

It will be understood that many additional changes in the details, materials, steps, and arrangement of parts, which have been herein described and illustrated in order to explain the nature of the invention, may be made by those skilled in the art within the principle and scope of the invention as expressed in the appended claims. Thus, the present invention is not intended to be limited to the specific embodiments in the examples given above and/or the attached drawings.

While embodiments of this invention have been shown and described, modifications thereof may be made by one skilled in the art without departing from the spirit or teaching of this invention. The embodiments described herein are exemplary only and not limiting. Many variations and modifications of the composition and method are possible and within the scope of the invention. Accordingly, the scope of protection is not limited to the embodiments described herein, but is only limited by the claims which follow, the scope of which shall include all equivalents of the subject matter of the claims.

What is claimed is:

1. A method for selective etching a substrate, the method comprising:
introducing a vapor of thionyl chloride (SOCl₂, CAS number: 7719-09-7) into a reaction chamber containing the substrate that has at least one metal or metal-containing films deposited thereon; and
allowing an etching reaction to proceed between SOCl₂ and the at least one metal or metal-containing films to selectively etch the at least one metal or metal-containing films, thereby etching the substrate.

2. The method of claim 1, further comprising:
maintaining a temperature of the reaction chamber from approximately 150° C. to approximately 600° C.

3. The method of claim 1, further comprising:
maintaining a pressure in the reaction chamber less than 100 Torr.

4. The method of claim 1, further comprising:
introducing a co-reactant into the reaction chamber in a continuous, pulsing or cyclic mode.

5. The method of claim 4, wherein the co-reactant is H₂, F₂, NO, O₂, COS, CO₂, CO, NO₂, SO₂O₃, Cl₂, HF, HBr or HCl.

6. The method of claim 1, wherein the vapor of thionyl chloride includes an inert gas.

7. The method of claim 6, wherein the inert gas is selected from N₂, Ar, Kr, Ne, He, Xe, or combinations thereof.

8. The method of claim 1, wherein SOCl₂ is not activated by a plasma.

9. The method of claim 1, wherein SOCl₂ is activated by a plasma.

10. The method of claim 1, wherein SOCl₂ is activated by heat.

11. The method of claim 1, wherein the substrate is a pattern containing silicon-containing and metal or metal-containing layers, so that the at least one metal or metal-containing films is selectively etched.

12. The method of claim 1, wherein the at least one metal or metal-containing film contains Mo-containing materials, W-containing materials, Ti-containing materials, Ta-containing materials, Nb-containing, Ru-containing, Rh-containing materials, Co-containing materials, Ni-containing materials, Fe-containing materials, Hf-containing materials, Zr-containing materials, V-containing materials or combinations thereof.

13. A method for cleaning reaction product deposits from interior surface of a reactor chamber or from a substrate within said reaction chamber, the method comprising:
exposing the reaction product deposits to a vapor, wherein the vapor comprises a vapor of thionyl chloride (SOCl₂, CAS number: 7719-09-7);
allowing an etching reaction to proceed between SOCl₂ and the reaction product deposits to convert the reaction product deposits into volatile products; and
evacuating the remaining SOCl₂ together with substantially all volatile products of the etching reaction.

14. The method of claim 13, further comprising:
maintaining a temperature of the reactor chamber from approximately 150° C. to approximately 600° C. while exposing the reaction product deposits to the vapor.

15. The method of claim 13, further comprising:
maintaining a pressure in the reaction chamber less than 100 Torr.

16. The method of claim 13, further comprising:
introducing a co-reactant into the reaction chamber in a continuous, pulsing or cyclic mode.

17. The method of claim 16, wherein the co-reactant is H₂, F₂, NO, O₂, COS, CO₂, CO, NO₂, SO₂O₃, Cl₂, HF, HBr or HCl.

18. The method of claim 13, wherein the reaction product deposits contains metal and metal-containing particles or films.

19. The method of claim 18, wherein the metal or metal-containing particles or films contain Mo-containing materials, W-containing materials, Ti-containing materials, Ta-containing materials, Nb-containing, Ru-containing, Rh-containing materials, Co-containing materials, Ni-containing materials, Fe-containing materials, Hf-containing materials, Zr-containing materials, V-containing materials or combinations thereof.

20. The method of claim 13, wherein the vapor of thionyl chloride includes an inert gas selected from N₂, Ar, Kr, Ne, He, Xe, or combinations thereof.
